(19) United States
(12) Patent Application Publication
(10) Pub. No.: US 2024/0243207 A1
(43) Pub. Date: Jul. 18, 2024

(54) OPTICAL DEVICE PACKAGE

(71) Applicant: Advanced Semiconductor Engineering, Inc., Kaohsiung (TW)

(72) Inventors: Hsiang-Cheng TSAI, Kaohsiung (TW); Ying-Chung CHEN, Kaohsiung (TW); Kuo-Hua LAI, Kaohsiung (TW)

(73) Assignee: Advanced Semiconductor Engineering, Inc., Kaohsiung (TW)

(21) Appl. No.: 18/096,355

(22) Filed: Jan. 12, 2023

(51) Int. Cl. H01L 31/0203; H01L 31/0216

(52) U.S. Cl. CPC H01L 31/0203; H01L 31/02164

(57) ABSTRACT

An optical device package is provided. The optical device package includes a sensor and a light-transmitting region. The sensor includes a sensing region. The light-transmitting region is at least partially in the sensor, and the light-transmitting region allows an external light to transmit therethrough and reach the sensing region. A width of the light-transmitting region adjacent to a level of the sensing region is equal to or smaller than a width of the sensing region.

### BACKGROUND

### 1. Technical Field

The present disclosure relates generally to an optical device package.

### 2. Description of the Related Art

Optical sensors are widely used in various applications. Currently, optical sensors and processors are usually arranged side-by-side over a substrate, and such arrangement may undesirably increase the size of the optical device package. In addition, as the size of the optical device package including optical sensors reduces, elements/components of the optical device package reduce in sizes accordingly; it is more challenging to increase the sensing accuracy of the optical device package.

### SUMMARY

In one or more embodiments, an optical device package includes a sensor and a light-transmitting region. The sensor includes a sensing region. The light-transmitting region is at least partially in the sensor, and the light-transmitting region allows an external light to transmit therethrough and reach the sensing region. A width of the light-transmitting region adjacent to a level of the sensing region is equal to or smaller than a width of the sensing region.

In one or more embodiments, an optical device package includes a sensor, a light-transmitting region, and a light-limiting structure. The sensor includes a sensing region. The light-transmitting region is adjacent to the sensing region and configured to allow an external light to transmit therethrough and reach the sensing region. The light-limiting structure partially exposes the sensing region from a top view perspective, and the sensing region and the light-limiting structure are at opposite sides of the sensor.

In one or more embodiments, an optical device package includes a carrier, a sensor, a light-transmitting region, and a light-limiting structure. The sensor is disposed over the carrier and includes a sensing region. The light-transmitting region is adjacent to the sensing region and configured to allow an external light to transmit therethrough and reach the sensing region. The light-limiting structure defines a light-transmitting area at a side of the light-transmitting region away from the sensing region. A distance between the sensing region and the light-transmitting area is configured to reduce a distance between a top surface of the light-limiting structure and the carrier.

### BRIEF DESCRIPTION OF THE DRAWINGS

Aspects of the present disclosure are best understood from the following detailed description when read with the accompanying drawings. It is noted that various features may not be drawn to scale, and the dimensions of the various features may be arbitrarily increased or reduced for clarity of discussion.

FIG. 1A illustrates a perspective view of an optical device package in accordance with some embodiments of the present disclosure.

FIG. 1B illustrates a cross-sectional view of an optical device package in accordance with some embodiments of the present disclosure.

FIG. 1B1 illustrates a top view of an optical device package in accordance with some embodiments of the present disclosure.

FIG. 1C illustrates a cross-sectional view of an optical device package in accordance with some embodiments of the present disclosure.

FIG. 1C1 illustrates a cross-sectional view of an optical device package in accordance with some embodiments of the present disclosure.

FIG. 1D illustrates a cross-sectional view of an optical device package in accordance with some embodiments of the present disclosure.

FIG. 1E illustrates a top view of a portion of an optical device package in accordance with some embodiments of the present disclosure.

FIG. 1F illustrates a cross-sectional view of an optical device package in accordance with some embodiments of the present disclosure.

FIG. 2A illustrates a cross-sectional view of an optical device package in accordance with some embodiments of the present disclosure.

FIG. 2B illustrates a cross-sectional view of a portion of an optical device package in accordance with some embodiments of the present disclosure.

FIG. 3A illustrates a perspective view of an optical device package in accordance with some embodiments of the present disclosure.

FIG. 3B illustrates a cross-sectional view of an optical device package in accordance with some embodiments of the present disclosure.

FIG. 3C illustrates a cross-sectional view of an optical device package in accordance with some embodiments of the present disclosure.

FIG. 3D illustrates a cross-sectional view of an optical device package in accordance with some embodiments of the present disclosure.

FIG. 3E illustrates a cross-sectional view of an optical device package in accordance with some embodiments of the present disclosure.

FIG. 4A illustrates a perspective view of an optical device package in accordance with some embodiments of the present disclosure.

FIG. 4B illustrates a cross-sectional view of an optical device package in accordance with some embodiments of the present disclosure.

FIG. 5A illustrates a perspective view of an optical device package in accordance with some embodiments of the present disclosure.

FIG. 5B illustrates a cross-sectional view of an optical device package in accordance with some embodiments of the present disclosure.

FIG. 5C illustrates a cross-sectional view of an optical device package in accordance with some embodiments of the present disclosure.

FIG. 6A illustrates a perspective view of an optical device package in accordance with some embodiments of the present disclosure.

FIG. 6B illustrates a cross-sectional view of an optical device package in accordance with some embodiments of the present disclosure.

FIG. 7A illustrates a cross-sectional view of an optical device package in accordance with some embodiments of the present disclosure.

FIG. 7B illustrates a cross-sectional view of an optical device package in accordance with some embodiments of the present disclosure.

FIG. 8A illustrates a perspective view of an optical device package in accordance with some embodiments of the present disclosure.

FIG. 8B illustrates a cross-sectional view of an optical device package in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

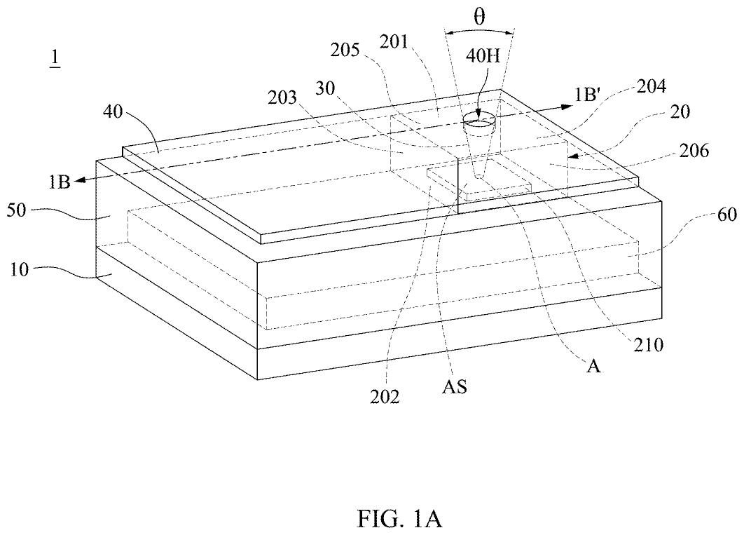

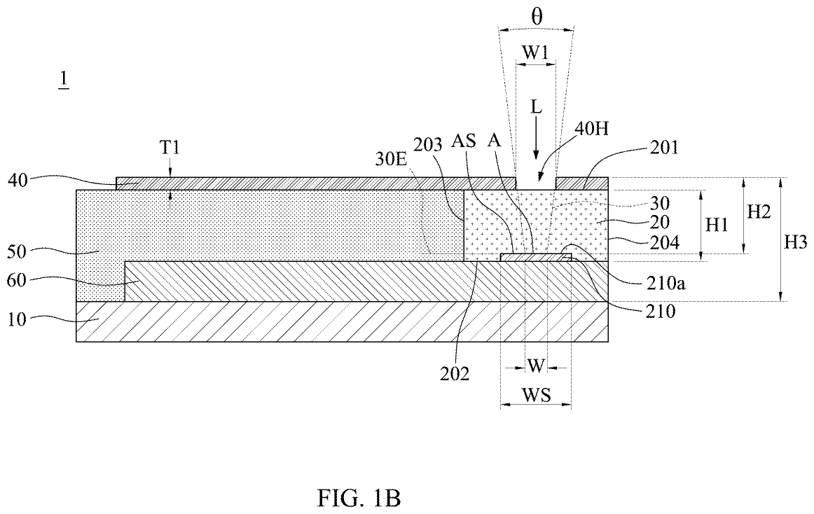

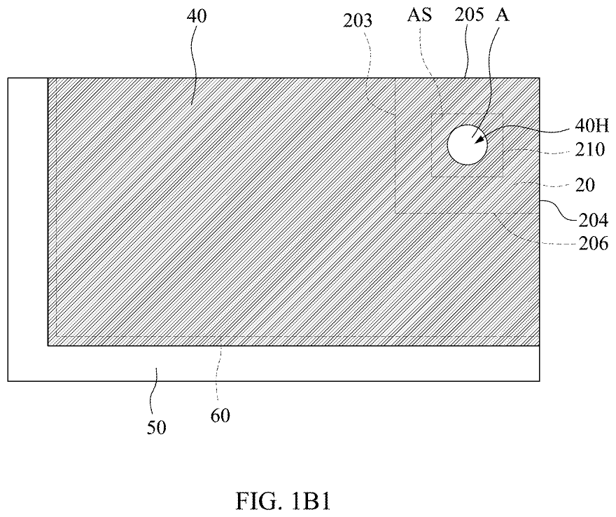

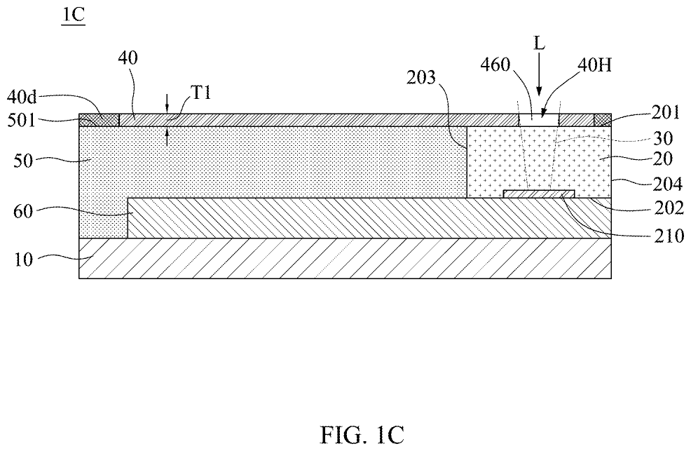

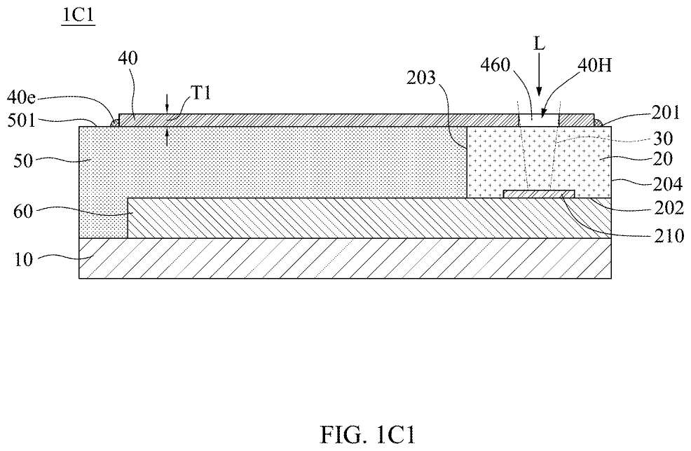

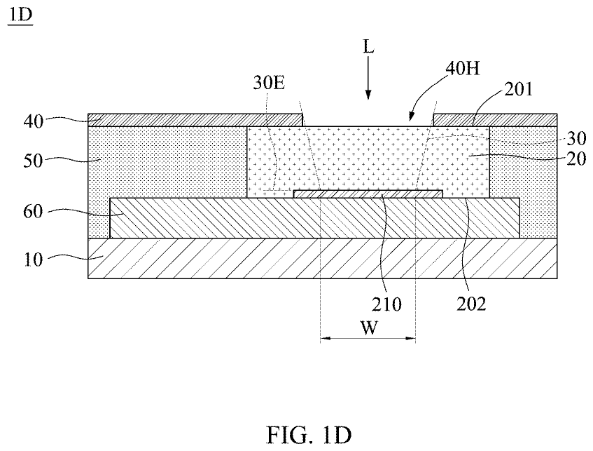

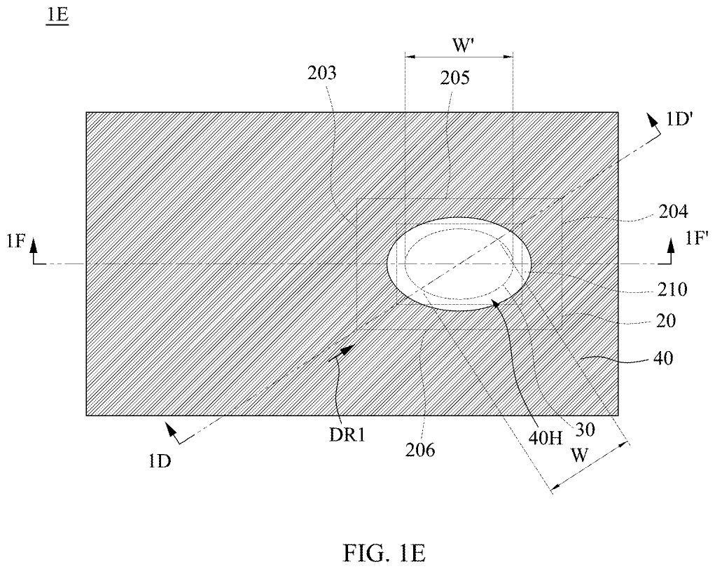

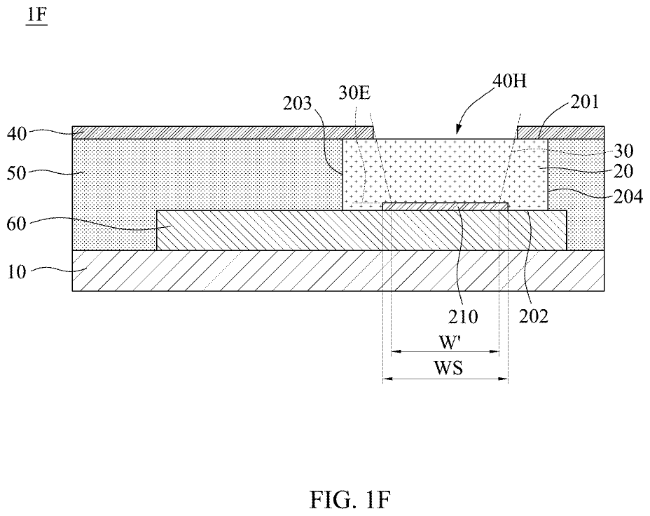

FIG. 1A illustrates a cross-sectional view of an optical device package 1 in accordance with some embodiments of the present disclosure. FIG. 1B illustrates a cross-sectional view of an optical device package 1 in accordance with some embodiments of the present disclosure. FIG. 1B1 illustrates a top view of an optical device package 1 in accordance with some embodiments of the present disclosure. In some embodiments, FIG. 1B illustrates a cross-sectional view along line 1B-1B′ in FIG. 1A. In some embodiments, FIG. 1B1 illustrates a top view of the optical device package 1 shown in FIG. 1A. The optical device package 1 includes a carrier 10, a sensor 20, a light-transmitting region 30, a light-blocking layer 40, an encapsulant 50, and an electronic component 60.

The carrier 10 may include, for example, a printed circuit board, such as a paper-based copper foil laminate, a composite copper foil laminate, or a polymer-impregnated glass-fiber-based copper foil laminate. The carrier 10 may include an interconnection structure, which may include such as a plurality of conductive traces and/or a plurality of conductive vias. The interconnection structure may include a redistribution layer (RDL) and/or a grounding element. In some embodiments, the carrier 10 includes a ceramic material or a metal plate. In some embodiments, the carrier 10 may include a substrate, such as an organic substrate or a leadframe. In some embodiments, the carrier 10 may include a two-layer substrate, which includes a core layer, and a conductive material and/or structure disposed on an upper surface and a bottom surface of the carrier 10. The conductive material and/or structure may include a plurality of traces. The carrier 10 may include one or more conductive pads in proximity to, adjacent to, or embedded in and exposed at an upper surface and/or a bottom surface of the carrier 10. The carrier 10 may include a solder resist (not shown) on the upper surface and/or the bottom surface of the carrier 10 to fully expose or to expose at least a portion of the conductive pads for electrical connections. In some embodiments, the carrier 10 is light-blocking or non-transmissive. In some embodiments, the carrier 10 is formed of or includes a material opaque or light-blocking (or non-transmissive) to the external light L.

The sensor 20 may be disposed over the carrier 10. The sensor 20 may have a surface 201 (also referred to as “a top surface” or “a light-receiving surface”), a surface 202 (also referred to as “a bottom surface”) opposite to the surface 201, and surfaces 203, 204, 205, and 206 (also referred to as “lateral surfaces”). The sensor 20 has a height H1 extending from the surface 201 to the surface 202. In some embodiments, the sensor 20 includes a sensing region 210. In some embodiments, the sensing region 210 is configured to receive or detect an external light L from outside of the optical device package 1. In some embodiments, the sensing region 210 is away or distal from the surface 201. With the design of the sensing region 210 and the light-limiting structure being at opposite sides of the sensor 20, the electrical path may be shortened, and thus the resistance can be reduced. In addition, with the sensing region 210 facing the electronic component 60, the electrical connection between the sensor 20 and the electronic component 60 may be attained by flip-chip technique instead of wire-bond technique, which requires space for accommodating bonding wires above the sensor 20. Therefore, the top surface of the sensor 20 can be substantially aligned with the top surface 501 of the encapsulant 50, and thus noise resulted from bonding wires can be reduced. In some embodiments, the surfaces 204 and 205 of the sensor 20 are exposed to an outside of the optical device package 1. In some embodiments, the surfaces 204 and 205 of the sensor 20 are exposed to air. The optical device package 1 having surfaces 204 and 205 of the sensor 20 exposed may be a wafer level structure. In some embodiments, the sensor 20 is configured to receive to detect a light having a wavelength from about 2 μm to about 9 μm, or from 2 μm to about 7 μm. The sensor 20 may be a Mid-Infrared (MIR) photodiode. In some embodiments, the sensor 20 is an optical temperature sensor.

The light-blocking layer 40 may be disposed over the sensor 20. In some embodiments, the light-blocking layer 40 is over the sensing region 210. In some embodiments, the light-blocking layer 40 contacts the sensor 20. In some embodiments, the light-blocking layer 40 is or includes a light-blocking sheet. In some embodiments, the light-blocking layer 40 is or includes a metal layer or a metal plate. In some embodiments, the light-blocking layer 40 is or includes a plated metal layer. With the plated metal layer having a thickness less than a thickness of a metal plate, the light-blocking layer 40 being or including a plated metal layer can have a reduced thickness, and thus the overall thickness of the optical device package 1 can be reduced as well. In some embodiments, the light-blocking layer 40 partially covers the surface 201 of the sensor 20. In some embodiments, the light-blocking layer 40 defines an opening 40H exposing a portion of the surface 201 (or the top surface) of the sensor 20. The opening 40H may be formed by laser drilling or mechanical drilling. The opening 40H having a width W1 of less than 100 μm may be formed by laser drilling, the opening 40H having a width W1 from about 100 μm to about 200 μm may be formed by laser drilling or mechanical drilling, and the opening 40H having a width W1 greater than about 200 μm may be formed by mechanical drilling. In some embodiments, the opening 40H of the light-blocking layer 40 being a plated metal layer may have the width W1 smaller than that of the opening 40H of the light-blocking layer 40 being a metal plate. In some embodiments, the light-blocking layer 40 has a thickness T1, and a depth of the opening 40H equals to the thickness T1 of the light-blocking layer 40. In some embodiments, the light-blocking layer 40 is formed of or includes a material opaque or light-blocking (or non-transmissive) to the external light L. In some embodiments, the light-blocking layer 40 may include, for example, aluminum, copper, chromium, tin, gold, silver, nickel or stainless steel, or a mixture, an alloy, or other combination thereof.

The encapsulant 50 may be disposed between the light-blocking layer 40 and the carrier 10. In some embodiments, the encapsulant 50 encapsulates the sensor 20 and the light-blocking layer 40. In some embodiments, the encapsulant 50 encapsulates the surfaces 202 and 206 (or the lateral surfaces) of the sensor 20. In some embodiments, the surfaces 204 and 205 are exposed by the encapsulant 50. In some embodiments, the encapsulant 50 is formed of or includes a material opaque or light-blocking (or non-transmissive) to the external light L. The encapsulant 50 may include an epoxy resin having fillers, a molding compound (e.g., an epoxy molding compound or other molding compound), polyimide, a phenolic compound or material, a material with a silicone dispersed therein, or a combination thereof. In some embodiments, the light-blocking layer 40 partially covers the top surface 501 of the encapsulant 50. In some embodiments, an edge or a lateral surface of the light-blocking layer 40 is recessed with respect to an edge or a lateral surface of the encapsulant 50. In some embodiments, with the aforesaid design, the cutting operation in the manufacturing process of the optical device package may be performed on the relatively soft encapsulant 50 instead of the relatively rigid light-blocking layer 40 (e.g., a metal layer), and thus the yield may be increased. In addition, while the exposed portion of the top surface 501 being relatively distal from the top surface 201 of the sensor 20, the noise or thermal radiation resulted from the external light L that may affect the sensor 20 can be minimized.

The light-transmitting region 30 may be adjacent to the sensing region 210 of the sensor 20. The light-transmitting region 30 may be at least partially in the sensor 20. In some embodiments, the light-transmitting region 30 includes a portion of the sensor 20. In some embodiments, the light-transmitting region 30 extends from the surface 201 to the sensing region 210 of the sensor 20, and the light-transmitting region 30 allows the external light L to transmit therethrough and reach the sensing region 210 of the sensor 20. In some embodiments, at least a portion of the sensing region 210 is embedded in the light-transmitting region 30. In some embodiments, a width W of a portion of the light-transmitting region 30 proximal to the sensing region 210 is less than a width of a portion of the light-transmitting region 30 distal from the sensing region 210 (e.g., the width W1 of the opening 40H). In some embodiments, the light-transmitting region 30 includes a through hole (e.g., the opening 40H) through which the external light L transmits to reach the sensing region 210. In some embodiments, the light-transmitting region 30 is surrounded by a light-blocking structure and configured to allow the external light L to transmit therethrough and reach the sensing region 210. In some embodiments, the light-transmitting region 30 is configured to allow mainly the external light L having a wavelength range excluding a visible spectrum to transmit therethrough and reach the sensing region 210. In some embodiments, the light-transmitting region 30 is configured to allow, specifically, only the external light L having a wavelength range excluding a visible spectrum to transmit therethrough and reach the sensing region 210. In some embodiments, the light-transmitting region 30 is configured to allow only the external light L being a non-visible light to transmit therethrough and reach the sensing region 210. The external light L that transmits through the light-transmitting region 30 may have a wavelength range of 2 μm to 7 μm, 2 μm to 9 μm, 3 μm to 8 μm (i.e., MIR), less than 380 nm, and greater than 780 nm. The light-blocking structure may include the light-blocking layer 40 and the encapsulant 50

In some embodiments, a height H2 of the light-transmitting region 30 defines a width W of the light-transmitting region 30 at or adjacent to a level 30E (also referred to as “an elevation”) of the sensing region 210. The level 30E of the sensing region 210 may refer to the level or elevation of a top surface 210a of the sensing region 210 or the level or elevation of a bottom surface (e.g., the surface 202) of the sensing region 210. In some embodiments, the height H2 substantially equals to a sum of the height H1 of the sensor 20 and the thickness T1 of the light-blocking layer 40. In some embodiments, the width W of the light-transmitting region 30 at or adjacent to the level 30E of the sensing region 210 is equal to or smaller than a width WS of the sensing region 210. In some embodiments, the width W of the light-transmitting region 30 refers to the width of a cross-section of the light-transmitting region 30 overlapping or very close to the top surface 210a or the bottom surface (or the surface 202) of the sensing region 210. In some embodiments, an area A of the light-transmitting region 30 at or adjacent to the level 30E of the sensing region 210 is equal to or smaller than an area AS of the sensing region 210. In some embodiments, the area A of the light-transmitting region 30 refers to the area of a cross-section of the light-transmitting region 30 overlapping or very close to the top surface 210a or the bottom surface (or the surface 202) of the sensing region 210. A field-of-view (FOV) of the optical device package 1 refers to a solid angle through which the sensor 20 is sensitive to the external light L, and an angle θ between lateral boundaries of the light-transmitting region 30 coincides with the FOV of the optical device package 1 in accordance with some embodiments of the present disclosure. In addition, with the design of the light-transmitting region 30 at least partially within the sensor 20, the height H2 of the light-transmitting region 30 may be maximized even with the overall thickness of the optical device package 1 is limited or cannot be further increased, such that the FOV of the optical device package 1 can be adjusted and/or reduced accordingly. The height H2 of the light-transmitting region 30 and/or the height H1 of the sensor 20 may be adjusted by adjusting the thickness T1 of the light-blocking layer 40, so as to adjust the FOV of the optical device package 1.

In some embodiments, the light-blocking structure includes the light-blocking layer 40 and the encapsulant 50, and the through hole (e.g., the opening 40H) of the light-transmitting region 30 is surrounded by the light-blocking structure (e.g., the light-blocking layer 40). In some embodiments, air is within the through hole (e.g., the opening 40H) of the light-transmitting region 30. In some embodiments, the light-blocking structure (e.g., the light-blocking layer 40) is at least partially over the sensing region 210. In some embodiments, the light-blocking structure is configured to define the angle θ between the lateral boundaries of the light-transmitting region 30. In some embodiments, the light-blocking structure includes an aperture (e.g., the opening 40H) allowing light transmission, and a width of the aperture (e.g., the width W1 of the opening 40H) defines the angle θ between lateral boundaries of the light-transmitting region 30. The width W1 may be less than about 200 μm.

In some embodiments, the light-blocking structure includes a first portion (e.g., the light-blocking layer 40) over the sensor 20 and surrounding the aperture (e.g., the opening 40H). In some embodiments, the light-blocking structure includes a second portion (e.g., the encapsulant 50) surrounding the lateral surfaces 203 and/or 206 of the sensor 20 and configured to block the external light L from entering the sensor 20 through the lateral surfaces 203 and/or 206. In some embodiments, the surfaces 204 and 205 are exposed by the second portion (e.g., the encapsulant 50) of the light-blocking structure. In some embodiments, the light-blocking structure is at least partially stacked over the sensor 20 and configured to block the external light L from transmitting therethrough and reaching the sensing region 210. In some embodiments, a projection of the light-blocking structure partially overlaps the sensing region 210 from a top view perspective.

In some embodiments, the optical device package 1 may include a light-limiting structure at least partially over the sensor 20 and configured to define a field-of-view (FOV) of the optical device package 1. In some embodiments, the light-limiting structure includes the light-blocking layer 40 (also referred to as “a first light-limiting structure”) with the opening 40H. In some embodiments, the light-limiting structure further includes the encapsulant 50 (also referred to as “a second light-limiting structure”) that encapsulates the surfaces 202 and 206 (or the lateral surfaces) of the sensor 20. In some embodiments, as shown in FIG. 1B1, the light-limiting structure (e.g., the light-blocking layer 40) partially exposes the sensing region 210 from a top view perspective. In some embodiments, the sensing region 201 may be partially exposed and observed by human eyes from a top view perspective. In some embodiments, the sensing region 210 may be partially exposed and observed through optical instruments, such as SEM, from a top view perspective. In some embodiments, as shown in FIG. 1B, the sensing region 210 and the light-limiting structure (e.g., the light-blocking layer 40) are at opposite sides of the sensor 20. In some embodiments, the light-limiting structure defines a light-transmitting area or an aperture (e.g., the opening 40H) allowing the external light L to transmit therethrough. In some embodiments, the light-limiting structure includes a first portion (e.g., the light-blocking layer 40) over the sensor 20 and surrounding the aperture. In some embodiments, the light-limiting structure includes a second portion (e.g., the encapsulant 50) surrounding the lateral surface (e.g., one or more of the surfaces 203, 204, 205, and 206) of the sensor 20 and configured to block the external light L from entering the sensor 20 through the lateral surface.

In some embodiments, the light-limiting structure has a light-transmitting area (e.g., the opening 40H) at a side of the light-transmitting region 30 away from the sensing region 210. In some embodiments, a distance (e.g., the height H2) between the sensing region 210 and the light-transmitting area (or the opening 40H) is configured to reduce a distance H3 between a top surface of the light-limiting structure and the carrier 10. In some embodiments, the distance between the sensing region 210 and the opening may refer to or substantially equal to the height H2 of the light-transmitting region 30, which may correspond to the FOV of the optical device package 1. Accordingly, increasing the size or the height H2 of the light-transmitting region 30 may reduce the FOV of the optical device package 1. While the FOV may contribute to the overall thickness or size of the optical device package 1, reducing the FOV may reduce the overall thickness or size of the optical device package 1. Accordingly, the distance (e.g., the height H2) between the sensing region 210 and the opening may be configured to reduce the distance H3 between the top surface of the light-limiting structure and the carrier 10. In some embodiments, a distance (e.g., a thickness of the electronic component 60) between the sensing region 210 and the carrier 10 is less than a distance between the sensing region (210) and the light-limiting structure (e.g., the light-blocking layer 40).

The electronic component 60 may be disposed over the carrier 10. In some embodiments, the sensor 20 is stacked over the electronic component 60. In some embodiments, the electronic component 60 is electrically connected to the sensor 20. In some embodiments, the electronic component 60 is configured to control the sensor 20. In some embodiments, the encapsulant 50 encapsulates the sensor 20 and the electronic component 60. In some embodiments, the electronic component 60 is electrically connected to the carrier 10. The electrical connection may be attained by way of flip-chip or wire-bond techniques. The electrical connection may be attained by conductive vias (e.g., TSVs) penetrating the electronic component 60. The electronic component 60 may include a processing component, such as an ASIC, an FPGA, a GPU, or the like, or a combination thereof.

In some cases where the FOV of an optical device package is purely defined by the height of the sensor, the FOV of the optical device package equals to the FOV of the sensor and can be relatively large, e.g., from about 160° to about 180°. In contrast, according to some embodiments of the present disclosure, with the light-transmitting region 30 partially in the sensor 20 and having a width W at or adjacent to a level 30E of the sensing region 210 equal to or smaller than a width WS of the sensing region 210, the FOV of the optical device package 1 is not purely defined by the height H1 of the sensor 20. Therefore, the FOV of the optical device package 1 can be reduced to be smaller than the FOV of the sensor 20 (or the light-receiving range of the sensor 20), for example, less than about 160°, thus the noise can be reduced, and the sensing accuracy of the optical device package 1 can be increased.

In addition, according to some embodiments of the present disclosure, with the light-blocking structure (or the light-limiting structure, e.g., the light-blocking layer 40) at least partially stacked over the sensor 20 and configured to block an external light L from transmitting therethrough and reaching the sensing region 210, the overall volume of the optical device package 1 can be reduced. Moreover, according to some embodiments of the present disclosure, with the light-transmitting region 30 surrounded by the light-blocking structure and configured to allow the external light L to transmit therethrough and reach the sensing region 210, both of the FOV of the optical device package 1 and the overall volume of the optical device package 1 can be reduced. Moreover, the coverage or range of the FOV in a longitudinal direction, in a lateral direction, and/or in a diagonal direction of the optical device package 1 may be reduced by adjusting the light-transmitting area or the aperture of the light-limiting structure (e.g., the opening 40H of the light-blocking layer 40).

Furthermore, according to some embodiments of the present disclosure, the light-blocking structure includes a metal layer 40 contacting and exposing a portion of the top surface 201 of the sensor 20. As such, in addition to that the FOV of the optical device package 1 can be further reduced to be smaller than about 100° (e.g., smaller than about 60°), the overall volume of the optical device package 1 can be further reduced. Moreover, thermal radiation effects can be mitigated or prevented due to the metal material of the light-blocking structure since metal can reflect radiation heat, and thus it is beneficial to increasing the sensing accuracy of the sensor 20 serving as an optical temperature sensor.

Moreover, while the encapsulant 50 may absorb radiation heat of Mid-Infrared (MIR) or allow MIR to pass through, according to some embodiments of the present disclosure, the light-receiving surface of the light-transmitting region 30 is exposed by the encapsulant 50, and thus the noise resulted from radiation effects from the encapsulant 50 can be reduced. Therefore, the sensing accuracy of the sensor 20 can be increased.

FIG. 1C illustrates a cross-sectional view of an optical device package 1C in accordance with some embodiments of the present disclosure. The optical device package 1C is similar to the optical device package 1 in FIGS. 1A-1B, and the differences therebetween are described as follows.

In some embodiments, the optical device package 1C further includes a light-transmissive gel 460. In some embodiments, the light-transmissive gel 460 is filled in the aperture (e.g., the opening 40H of the light-blocking layer 40) of the light-blocking structure. In some embodiments, the light-transmissive gel 460 is within the through hole (e.g., the opening 40H) of the light-transmitting region 30. According to some embodiments of the present disclosure, the light-transmissive gel 460 can protect a portion of the top surface 201 exposed from the light-blocking layer 40. In addition, the FOV of the optical device package 1C may be adjusted according to actual needs by using the light-transmissive gel 460 with a predetermined refractive index.

In some embodiments, the light-blocking layer 40 partially covers the surface 201 of the sensor 20. In some embodiments, the optical device package 1C further includes a light-blocking layer 40d over the encapsulant 50. In some embodiments, the light-blocking layer 40d covers a top surface 501 of the encapsulant 50. In some embodiments, the light-blocking layer 40d covers the surface 201 of the sensor 20. The light-blocking layer 40d may be or include a passivation layer, a dielectric layer, or an insulative layer.

In some embodiments, the optical device package 1C may include a light-limiting structure at least partially over the sensor 20 and configured to define a field-of-view (FOV) of the optical device package 1C. In some embodiments, the light-limiting structure includes the light-blocking layer 40 with the opening 40H filled with the light-transmissive gel 460. In some embodiments, the light-limiting structure further includes the light-blocking layer 40d that covers the surface 201 of the sensor 20.

FIG. 1C1 illustrates a cross-sectional view of an optical device package 1C1 in accordance with some embodiments of the present disclosure. The optical device package 1C1 is similar to the optical device package 1C in FIG. 1C, and the differences therebetween are described as follows.

In some embodiments, the optical device package 1C further includes a light-blocking layer 40e over the encapsulant 50. In some embodiments, the light-blocking layer 40e partially covers the top surface of the encapsulant 50. The light-blocking layer 40e may be or include a light-blocking gel or a non-transmissive gel protruded from between the light-blocking layer 40 and the encapsulant 50.

FIG. 1D illustrates a cross-sectional view of an optical device package 1D in accordance with some embodiments of the present disclosure. The optical device package 1D is similar to the optical device package 1 in FIGS. 1A-1B, and the differences therebetween are described as follows.

In some embodiments, the encapsulant 50 covers or encapsulates the lateral surfaces (e.g., the surfaces 203 to 206) of the sensor 20. In some embodiments, the sensor 20 does not have any lateral surface exposed by the encapsulant 50. The encapsulant 50 may be opaque or light-blocking (or non-transmissive) to the external light L, and thus noise resulted from the external light L transmitting through the lateral surface of the sensor 20 to reach the sensing region 210 can be reduced or prevented. In addition, with the design of the lateral surfaces (e.g., the surfaces 203 to 206) of the sensor 20 covered by the encapsulant 50, the cutting operation in the manufacturing process of the optical device package may be performed on the relatively soft encapsulant 50 instead of the relatively rigid light-blocking layer 40 (e.g., a metal layer), and thus the yield may be increased.

FIG. 1E illustrates a top view of a portion of an optical device package 1E in accordance with some embodiments of the present disclosure. In some embodiments, FIG. 1D illustrates a cross-sectional view along line 1D-1D′ in FIG. 1E. The optical device package 1E is similar to the optical device package 1 in FIGS. 1A-1B, and the differences therebetween are described as follows.

In some embodiments, also referring to FIG. 1D, the width W of the light-transmitting region 30 at or adjacent to the level 30E of the sensing region 210 is in a direction DR1 substantially parallel to a diagonal line of the sensing region 210 from a top view perspective. In some embodiments, the light-transmitting region 30 at or adjacent to the level 30E of the sensing region 210 may have a width W′ substantially in parallel to a side (e.g., the surface 206) of the sensing region 210 from a top view perspective.

FIG. 1F illustrates a cross-sectional view of an optical device package in accordance with some embodiments of the present disclosure. In some embodiments, FIG. 1F illustrates a cross-sectional view along line 1F-1F′ in FIG. 1E. The optical device package 1F is similar to the optical device package 1 in FIGS. 1A-1B, and the differences therebetween are described as follows.

In some embodiments, the light-transmitting region 30 at or adjacent to the level 30E of the sensing region 210 may have a width W′ smaller than the width WS of the sensing region 210. In some embodiments, also referring to FIG. 1E, the width W′ is substantially in parallel to a side (e.g., the surface 206) of the sensing region 210 from a top view perspective. In some embodiments, referring to FIGS. 1D-1F, the light-limiting structure includes a portion (e.g., the encapsulant 50) surrounding the lateral surface (e.g., the surfaces 203, 204, 205, and 206) of the sensor 20 and configured to block the external light L from entering the sensor 20 through the surfaces 203, 204, 205, and 206.

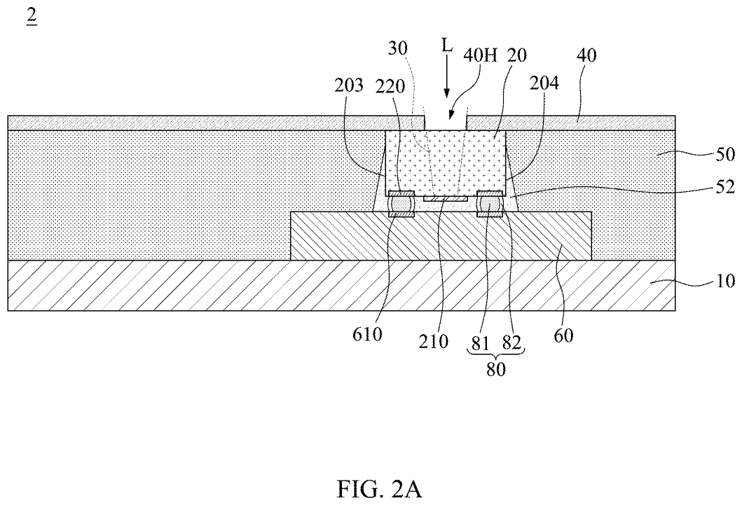

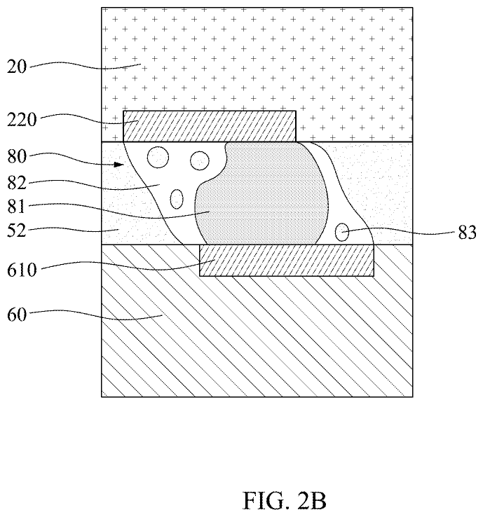

FIG. 2A illustrates a cross-sectional view of an optical device package 2 in accordance with some embodiments of the present disclosure. FIG. 2B illustrates a cross-sectional view of a portion of an optical device package 2 in accordance with some embodiments of the present disclosure. The optical device package 2 is similar to the optical device package 1 in FIGS. 1A-1B, and the differences therebetween are described as follows.

In some embodiments, the optical device package 2 further includes one or more connection structures 80 and a protective gel 52. In some embodiments, the sensor 20 is flip-chip bonded to the electronic component 60 through the connection structures 80. According to some embodiments of the present disclosure, with the sensor 20 stacked on and flip-chip bonded to the electronic component 60, space for accommodating bonding wires can be omitted, and thus the x-y size of the optical device package 2 can be effectively reduced.

In some embodiments, the sensor 20 includes a pad 220. In some embodiments, electronic component 60 includes a pad 610 facing the pad 220. In some embodiments, the connection structure 80 connects the pad 220 to the pad 610. In some embodiments, the connection structure 80 electrically connects the electronic component 60 and the sensor 20 through the pad 220 and the pad 610. In some embodiments, the pad 220 is formed of or includes gold. In some embodiments, the pad 610 is formed of or includes aluminum.

In some embodiments, the connection structure 80 includes a conductive bulk connector 81 and a conductive gel 82. The conductive gel 82 may include one or more fillers 83. In some embodiments, the connection structure 80 includes a material identical to one of the pad 220 or the pad 610. In some embodiments, the conductive bulk connector 81 is composed of a material identical to one of the pad 220 or the pad 610 and electrically connecting the electronic component 60 and the sensor 20. In some embodiments, the conductive bulk connector 81 is formed of or includes gold. In some embodiments, the conductive gel 82 is adjacent to the conductive bulk connector 81, the pad 220, and the pad 610. In some embodiments, the conductive gel 82 directly or physically contacts the conductive bulk connector 81, the pad 220, and the pad 610. In some embodiments, the fillers 83 are dispersed in the conductive gel 82. In some embodiments, a size of the fillers 83 is less than a size of the conductive bulk connector 81. In some embodiments, a ratio of the size of the conductive bulk connector 82 to the size of the fillers 82 may be greater than about 5, about 7, about 9, or about 12. In some embodiments, the fillers 83 are formed of or include a metal material, e.g., silver. In some embodiments, the conductive gel 82 including the fillers 83 is or includes a conductive gel.

In some embodiments, the protective gel 52 covers or encapsulates the conductive gel 82. In some embodiments, the protective gel 52 further covers the surfaces 203 to 206 (or the lateral surfaces) of the sensor 20. In some embodiments, the protective gel 52 is formed of or includes a material opaque or light-blocking (or non-transmissive) to the external light L. In some embodiments, the protective gel 52 is or includes an underfill. The protective gel 52 may include an epoxy resin having fillers, a molding compound (e.g., an epoxy molding compound or other molding compound), polyimide, a phenolic compound or material, a material with a silicone dispersed therein, or a combination thereof.

According to some embodiments of the present disclosure, the connection structure 80 includes the conductive bulk connector 81 composed of a material identical to one of the pad 220 or the pad 610. Thus, even if the materials of the pad 220 and the pad 610 have a poor miscibility which may lead to a poor electrical connection between the pad 220 and the pad 610, the conductive bulk connector 81 can provide an excellent electrical connection interface between the materials of the pad 220 and the pad 610. Therefore, the electrical connection between the sensor 20 and the electronic component 60 can be attained through the connection structure 80.

In addition, according to some embodiments of the present disclosure, the connection structure 80 further includes the conductive gel 82. Thus, even if the conductive bulk connector 81 is not aligned with the pad 220 and/or the pad 610 during the manufacturing process, the conductive gel 82 can provide an additional electrical connection interface or medium for the conductive bulk connector 81. Therefore, the electrical connection between the sensor 20 and the electronic component 60 can be attained through the conductive bulk connector 81 together with the conductive gel 82. Moreover, the conductive gel 82 can be further beneficial to fix or fasten the conductive bulk connector 81 at a predetermined position prior to curing the conductive gel 82 during the manufacturing process, which can increase the yield.

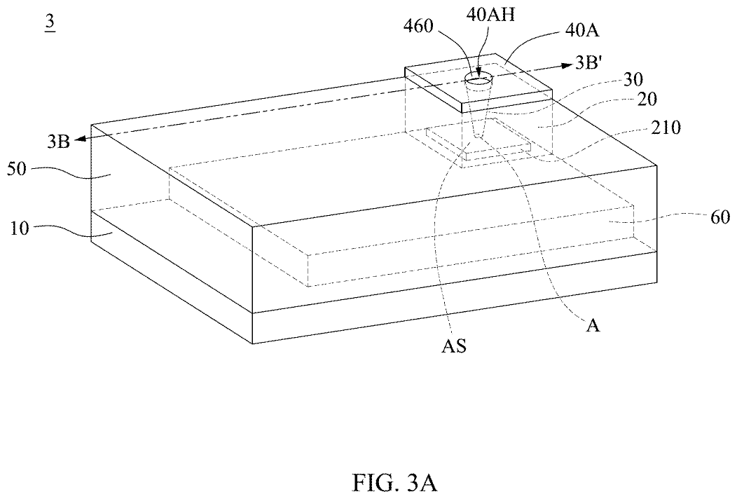

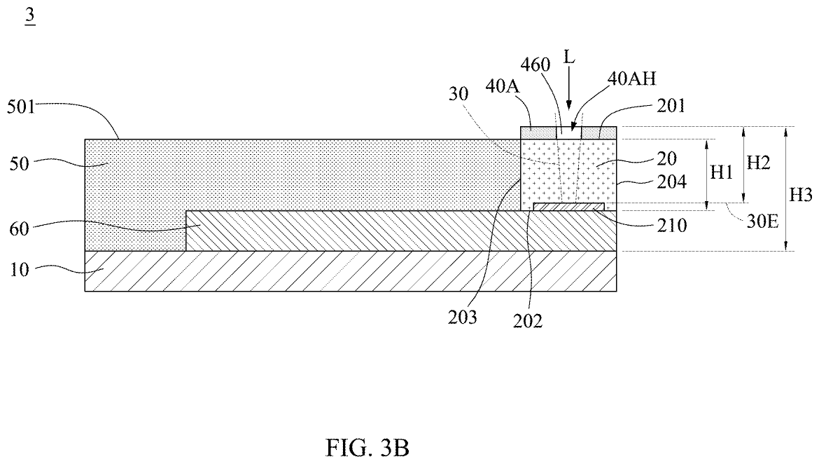

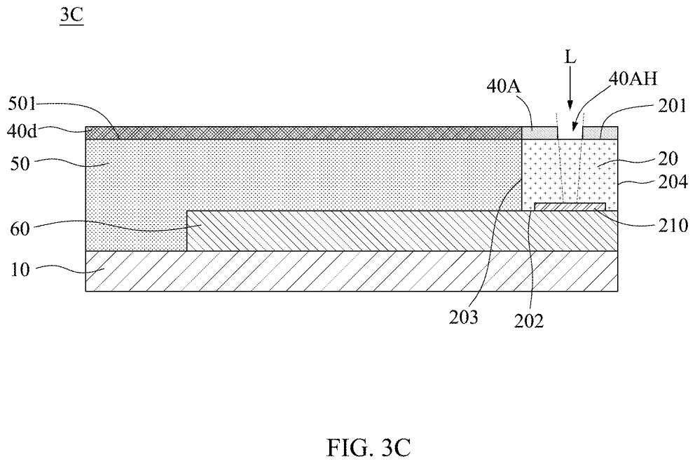

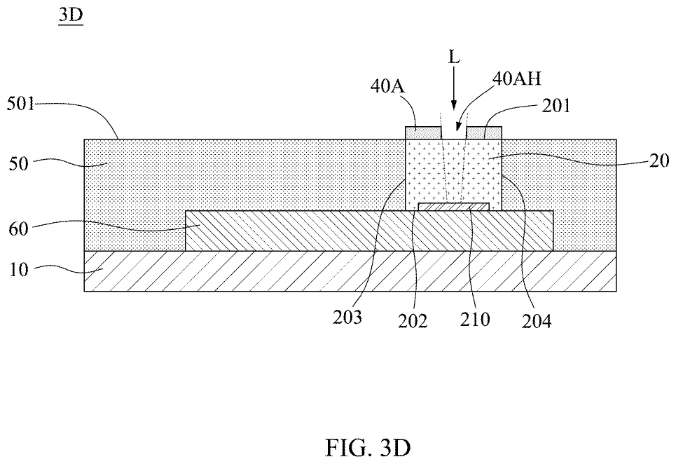

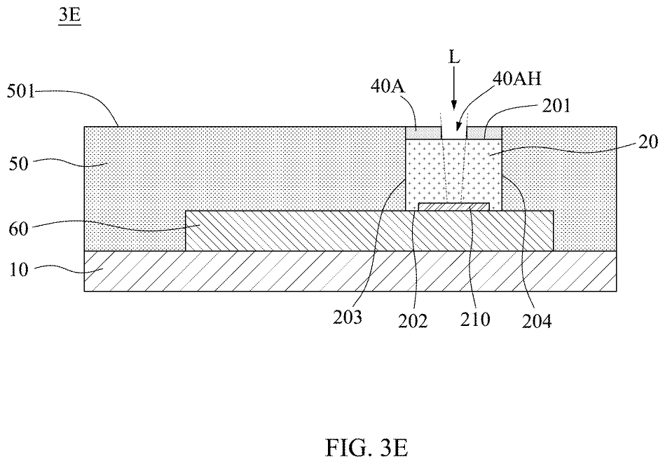

FIG. 3A illustrates a perspective view of an optical device package 3 in accordance with some embodiments of the present disclosure. FIG. 3B illustrates a cross-sectional view of an optical device package 3 in accordance with some embodiments of the present disclosure. In some embodiments, FIG. 3B illustrates a cross-sectional view along line 3B-3B′ in FIG. 3A. The optical device package 3 is similar to the optical device package 1 in FIGS. 1A-1B, and the differences therebetween are described as follows.

In some embodiments, the light-blocking layer 40A covers the surface 201 of the sensor 20. In some embodiments, the light-blocking layer 40A contacts the sensor 20. In some embodiments, the light-blocking layer 40A is free from covering or overlapping the top surface 501 of the encapsulant 50. In some embodiments, the light-blocking layer 40A is or includes a light-blocking sheet. In some embodiments, the light-blocking layer 40A is or includes a metal layer or a metal plate. In some embodiments, the light-blocking layer 40A is or includes a plated metal layer. In some embodiments, the light-blocking layer 40A is formed of or includes a material opaque or light-blocking (or non-transmissive) to the external light L. In some embodiments, the light-blocking layer 40A may include, for example, aluminum, copper, chromium, tin, gold, silver, nickel or stainless steel, or a mixture, an alloy, or other combination thereof.

In some embodiments, the light-blocking layer 40A defines an opening 40AH exposing a portion of the surface 201 (or the top surface) of the sensor 20. In some embodiments, the light-transmitting region 30 includes a through hole (e.g., the opening 40AH) surrounded by the light-blocking layer 40A. In some embodiments, air is within the through hole (e.g., the opening 40AH) of the light-transmitting region 30. The height H2 of the light-transmitting region 30 may be adjusted by adjusting the thickness T1 of the light-blocking layer 40A, so as to adjust the FOV of the optical device package 3.

FIG. 3C illustrates a cross-sectional view of an optical device package 3C in accordance with some embodiments of the present disclosure. The optical device package 3C is similar to the optical device package 3 in FIGS. 3A-3B, and the differences therebetween are described as follows.

In some embodiments, air is within the aperture (e.g., the opening 40AH of the light-blocking layer 40A) of the light-blocking structure. In some embodiments, air is within the through hole (e.g., the opening 40AH) of the light-transmitting region 30.

In some embodiments, the optical device package 3C further includes a light-blocking layer 40d over the encapsulant 50. In some embodiments, the light-blocking layer 40d covers the top surface 501 of the encapsulant 50. In some embodiments, the light-blocking layer 40d is free from covering or overlapping the surface 201 of the sensor 20. The light-blocking layer 40d may be or include a passivation layer, a dielectric layer, or an insulative layer. According to some embodiments of the present disclosure, the light-blocking layer 40A formed of or including a metal material can both block the external light L and mitigate or prevent radiation effects. In addition, the light-blocking layer 40d including a non-metal material that is less costly than the metal material further blocks the external light L from above the encapsulant 50 and the sensor 20, thus noise from above the sensor 20 can be significantly reduced, and the cost can be reduced as well.

FIG. 3D illustrates a cross-sectional view of an optical device package 3D in accordance with some embodiments of the present disclosure. The optical device package 3D is similar to the optical device package 3 in FIGS. 3A-3B, and the differences therebetween are described as follows.

In some embodiments, the encapsulant 50 covers or encapsulates the lateral surfaces (e.g., the surfaces 203 to 206) of the sensor 20. In some embodiments, the sensor 20 does not have any lateral surface exposed by the encapsulant 50. In some embodiments, the light-limiting structure includes a first portion (e.g., the light-blocking layer 40A) (also referred to as “a first light-limiting structure”) over the sensor 20 and surrounding the aperture. In some embodiments, the first portion (e.g., the light-blocking layer 40A or the first light-limiting structure) of the light-limiting structure has an outer edge substantially aligned with a lateral surface (e.g., the surfaces 203 to 206) of the sensor 20. The encapsulant 50 may be referred to as a second light-limiting structure.

FIG. 3E illustrates a cross-sectional view of an optical device package 3E in accordance with some embodiments of the present disclosure. The optical device package 3D is similar to the optical device package 3D in FIG. 3D, and the differences therebetween are described as follows.

In some embodiments, the light-limiting structure includes a first portion (e.g., the light-blocking layer 40A) over the sensor 20 and surrounding the aperture. In some embodiments, the light-limiting structure further includes a second portion (e.g., the encapsulant 50) encapsulating the sensor 20, and a top surface of the first portion (e.g., the light-blocking layer 40A) substantially aligns with the top surface 501 of the second portion (e.g., the encapsulant 50).

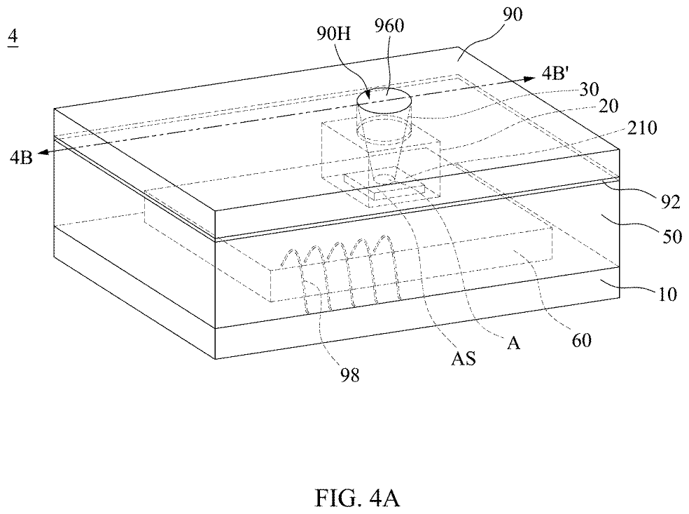

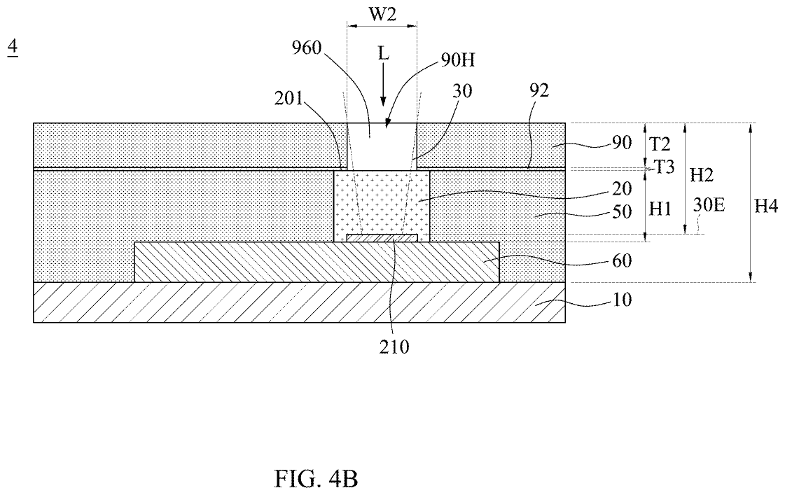

FIG. 4A illustrates a perspective view of an optical device package 4 in accordance with some embodiments of the present disclosure. FIG. 4B illustrates a cross-sectional view of an optical device package 4 in accordance with some embodiments of the present disclosure. In some embodiments, FIG. 4B illustrates a cross-sectional view along line 4B-4B′ in FIG. 4A. The optical device package 4 is similar to the optical device package 1 in FIGS. 1A-1B, and the differences therebetween are described as follows.

In some embodiments, the light-blocking structure of the optical device package 4 includes a light-blocking layer 90, an adhesive layer 92, and the encapsulant 50.

In some embodiments, the light-blocking layer 90 is over the sensor 20 and the encapsulant 50. In some embodiments, the light-blocking layer 90 is over the sensing region 210. In some embodiments, the light-blocking layer 90 contacts the sensor 20. In some embodiments, the light-blocking layer 90 is or includes a light-blocking sheet. In some embodiments, the light-blocking layer 90 is or includes a non-metal layer. The light-blocking layer 90 may be formed of or include liquid crystal polymer (LCP). In some embodiments, the light-blocking layer 90 partially covers the surface 201 of the sensor 20. In some embodiments, the light-blocking layer 90 defines an opening 90H exposing a portion of the surface 201 (or the top surface) of the sensor 20. In some embodiments, the light-blocking layer 90 has a thickness T2. In some embodiments, the light-transmitting region 30 includes a through hole (e.g., the opening 90H) surrounded by the light-blocking layer 90. In some embodiments, the light-blocking layer 90 is formed of or includes a material opaque or light-blocking (or non-transmissive) to the external light L. The optical device package 4 having all of the surfaces 203, 204, 205, and 206 of the sensor 20 covered by the encapsulant 50 may be a package level structure. The height H2 of the light-transmitting region 30 may be adjusted by adjusting the thickness T2 of the light-blocking layer 90, so as to adjust the FOV of the optical device package 4.

In some embodiments, the adhesive layer 92 (also referred to as “a connection layer”) adheres the light-blocking layer 90 to the encapsulant 50. In some embodiments, the adhesive layer 92 has a thickness T3, and a depth of the opening 90H equals to a sum of the thickness T2 of the light-blocking layer 90 and the thickness T3 of the adhesive layer 92. In some embodiments, the adhesive layer 92 is formed of or includes a material opaque or light-blocking (or non-transmissive) to the external light L. In some embodiments, the adhesive layer 92 may be formed of or include a conductive gel including a metal material (e.g., a silver gel), and thus thermal radiation effects can be mitigated or prevented. In some embodiments, the height H2 of the light-transmitting region 30 substantially equal to a sum of the height H1 of the sensor 20, the thickness T2 of the light-blocking layer 90, and the thickness T3 of the adhesive layer 92.

In some embodiments, the optical device package 4 further includes a light-transmissive gel 960. In some embodiments, the light-transmissive gel 960 is filled in the aperture (e.g., the opening 90H of the light-blocking layer 90) of the light-blocking structure. In some embodiments, the light-transmissive gel 960 is within the through hole (e.g., the opening 90H) of the light-transmitting region 30. In some embodiments, the light-blocking structure includes an aperture (e.g., the opening 90H) allowing light transmission, and a width W2 of the aperture (e.g., the opening 90H) defines the angle θ between lateral boundaries of the light-transmitting region 30. According to some embodiments of the present disclosure, the light-transmissive gel 960 can protect a portion of the top surface 201 exposed from the light-blocking layer 90. In addition, the FOV of the optical device package 4 may be adjusted according to actual needs by using the light-transmissive gel 960 with a predetermined refractive index.

In some embodiments, the optical device package 4 may include a light-limiting structure at least partially over the sensor 20 and configured to define a field-of-view (FOV) of the optical device package 4. In some embodiments, the light-limiting structure includes the light-blocking layer 90 (e.g., the non-metal layer) (also referred to as “a first light-limiting structure”) with the opening 90H filled with the light-transmissive gel 960. In some embodiments, the light-limiting structure further includes the adhesive layer 92. In some embodiments, the adhesive layer 92 (or the connection layer) is between the light-limiting structure and the sensor 20, and the adhesive layer 92 includes a light-blocking material. In some embodiments, the light-limiting structure has a light-transmitting area or an opening (e.g., the opening 90H) at a side of the light-transmitting region 30 away from the sensing region 210. In some embodiments, a distance (e.g., the height H2) between the sensing region 210 and the light-transmitting area (or the opening 90H) is configured to reduce a distance H4 between a top surface of the light-limiting structure and the carrier 10. The encapsulant 50 may be referred to as a second light-limiting structure.

In some embodiments, the optical device package 4 further includes conductive wires 98 electrically connecting the electronic component 60 to the carrier 10.

According to some embodiments of the present disclosure, with the design of the light-blocking layer 90 formed of or including LCP, which is a low-reflective material, noise resulted from light reflection can be reduced by reducing noise resulted from reflected light passing through the opening 90H to reach the sensing region 210. Thus, the width W2 of the aperture (e.g., the opening 90H) can be relatively large (e.g., greater than about 200 μm, or from about 450 μm to about 500 μm) without generation of noise from light reflection. Therefore, the light-blocking layer 90 may be formed by an injection operation, a laser drilling operation for forming a small through hole can be omitted, such that the processing cost can be significantly reduced.

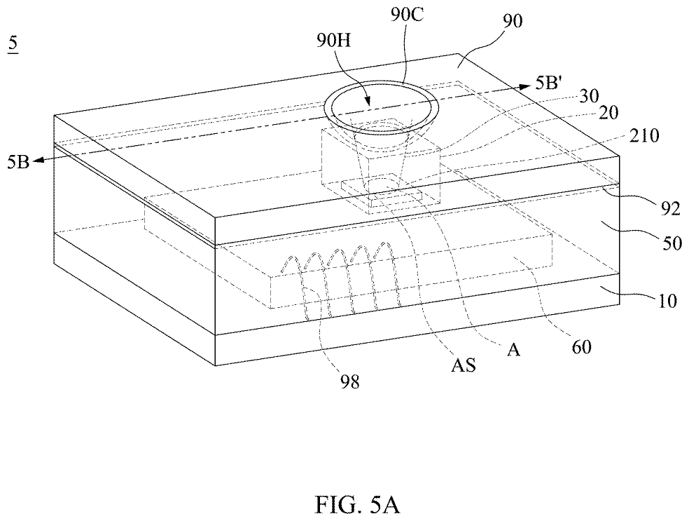

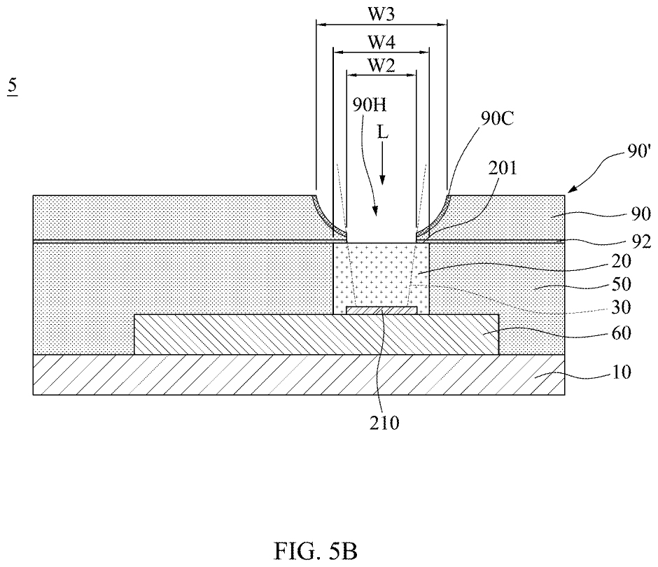

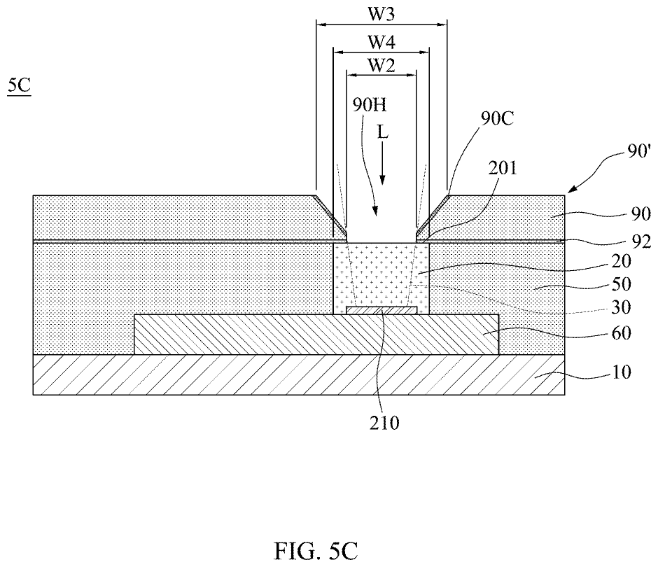

FIG. 5A illustrates a perspective view of an optical device package 5 in accordance with some embodiments of the present disclosure. FIG. 5B illustrates a cross-sectional view of an optical device package 5 in accordance with some embodiments of the present disclosure. In some embodiments, FIG. 5B illustrates a cross-sectional view along line 5B-5B′ in FIG. 5A. The optical device package 5 is similar to the optical device package 4 in FIGS. 4A-4B, and the differences therebetween are described as follows.

In some embodiments, the light-blocking structure includes a light-blocking layer 90 and a metal coating 90C on an inner wall of the opening 90H (or the through hole)). In some embodiments, the inner wall of the opening 90H may have a curved surface. The curved surface of the inner wall of the opening 90H illustrated in FIG. 5B may be formed by etching (with a suitable aspect ratio) or molding. The metal coating 90C may be formed by plating. The metal coating 90C may be formed of or include gold. In some embodiments, the light-blocking layer 90 is or includes a non-metal layer, and the metal coating 90C defines a lateral side of the light-transmitting region 30. The non-metal layer (i.e., the light-blocking layer 90) and the metal coating 90C collectively form a light-blocking sheet 90′ over the sensor 20 and the encapsulant 50. In some other embodiments, the metal coating 90C may be further formed on the top surface of the light-blocking layer 90.

According to some embodiments of the present disclosure, the metal coating 90C can mitigate or prevent radiation effects, and thus it is beneficial to increasing the sensing accuracy of the sensor 20 serving as an optical temperature sensor. In addition, the metal coating 90C is only formed on the inner wall of the opening 90H instead of being formed over the surface 201 of the sensor 20, thus the cost can be reduced.

In some embodiments, the optical device package 5 may include a light-limiting structure at least partially over the sensor 20 and configured to define a field-of-view (FOV) of the optical device package 5. In some embodiments, the light-limiting structure includes the light-blocking layer 90 (e.g., the non-metal layer) with the through hole (e.g., the opening 90H) and the metal coating 90C on an inner wall of the through hole. In some embodiments, the inner wall of the opening 90H is at least partially slanted and defining the through hole having a size (i.e., the width W2) smaller than a size (i.e., the width W4) of the surface 201 (or the top surface) of the sensor 20. In some embodiments, the through hole may have an opening defined by the slanted inner wall and having a size (i.e., the width W3) greater than the size (i.e., the width W4) of the surface 201 of the sensor 20. The width W2 may be greater than about 200 μm. The width W3 may be from about 450 μm to about 500 μm. In some embodiments, the light-limiting structure includes a first portion (e.g., the light-blocking layer 90 and the metal coating 90C) over the sensor 20 and surrounding the aperture. In some embodiments, the metal coating 90C defines a lateral side of the aperture. In some embodiments, the lateral side of the aperture (e.g., the opening 90H) is at least partially slanted, and the width W2 of the aperture is smaller than a width (e.g., the width WS) of the top surface 201 of the sensor 20. The at least partially slanted lateral side of the aperture is advantageous to reflect the large angle external light L out of the optical device package 5 so as to further reduce noise.

FIG. 5C illustrates a cross-sectional view of an optical device package 5C in accordance with some embodiments of the present disclosure. The optical device package 5C is similar to the optical device package 5 in FIGS. 5A-5B, and the differences therebetween are described as follows.

In some embodiments, the inner wall of the opening 90H may have an inclined surface. The inclined surface of the inner wall of the opening 90H illustrated in FIG. 5C may be formed by molding, laser drilling, mechanical drilling, punching press, or other suitable operations.

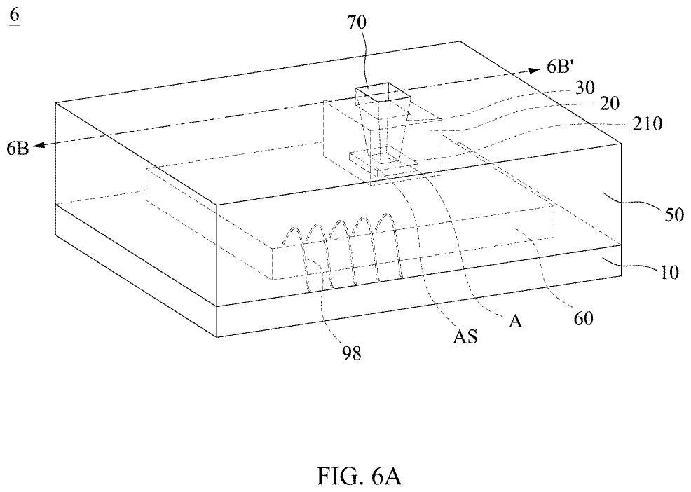

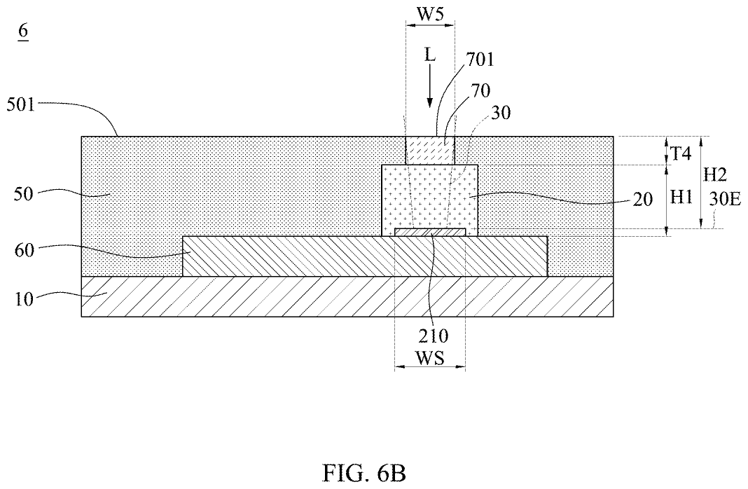

FIG. 6A illustrates a perspective view of an optical device package 6 in accordance with some embodiments of the present disclosure. FIG. 6B illustrates a cross-sectional view of an optical device package 6 in accordance with some embodiments of the present disclosure. In some embodiments, FIG. 6B illustrates a cross-sectional view along line 6B-6B′ in FIG. 6A. The optical device package 6 is similar to the optical device package 1 in FIGS. 1A-1B, and the differences therebetween are described as follows.

In some embodiments, the optical device package 6 includes a dummy die 70 stacked over the sensor 20. In some embodiments, the dummy die 70 is configured to allow the external light L to pass and reach the sensing region 210. In some embodiments, the dummy die 70 is or includes a semiconductor layer (e.g., a silicon layer) without active elements or circuit layers formed therein. In some embodiments, the FOV of the optical device package 6 may be adjusted by adjusting a thickness T4 of the dummy die 70 and/or a width W5 of the dummy die 70. The FOV of the optical device package 6 may be reduced by increasing the thickness T4 and/or reducing a horizontal area (e.g., the width W5) of the dummy die 70. That is, the dimension or size of the dummy die 70 may be adjusted to adjust the FOV of the optical device package 6.

In some embodiments, the dummy die 70 contacts the sensor 20. In some embodiments, the light-transmitting region 30 includes a portion of the dummy die 70. In some embodiments, the light-transmitting region 30 includes the dummy die 70 through which the external light L transmits to reach the sensing region 210. In some embodiments, the dummy die 70 is surrounded by the light-blocking structure (e.g., the encapsulant 50). In some embodiments, the height H2 of the light-transmitting region 30 substantially equals to a sum of the height H1 of the sensor 20 and the thickness T4 of the dummy die 70. In some embodiments, the light-blocking structure includes the encapsulant 50 encapsulating the sensor 20 and the dummy die 70. In some embodiments, a top surface 701 of the dummy die 70 is exposed from and substantially level with the top surface 501 of the encapsulant 50. In some embodiments, the sensing region 210 is away or distal from a bottom of the dummy die 70. In some embodiments, the width W5 of the dummy die 70 is less than the width WS of the sensing region 210.

In some embodiments, the dummy die 70 contacts the sensor 20, the encapsulant 50 encapsulates the sensor 20 and the dummy die 70, and the encapsulant 50 is configured to block the external light L from entering the sensing region 210. In some embodiments, the dummy die 70 may have a size of as small as about 150 μm*150 μm. The FOV of the optical device package 6 may be further reduced by including the dummy die 70 having a predetermined thickness T4 without increasing the horizontal area of the optical device package 6. For example, the dummy die 70 can be used to further reduce the FOV while the horizontal area of the optical device package cannot be further reduced due to manufacturing processing limit. In some embodiments, loss of the external light L transmitting in a direction substantially perpendicular to the top surface 201 of the sensor 20 (e.g., small angle light) is less than loss of the external light L transmitting in a direction forming an angle of greater than about 45° with the top surface 201 of the sensor 20 (e.g., large angle light). Therefore, the dummy die 70 is advantageous to increasing the signal/noise (S/N) ratio of the received light (or received optical signal).

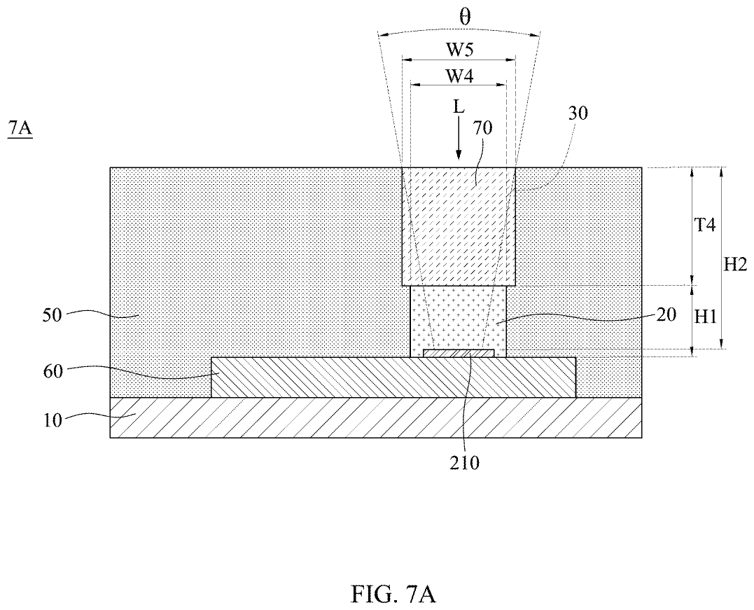

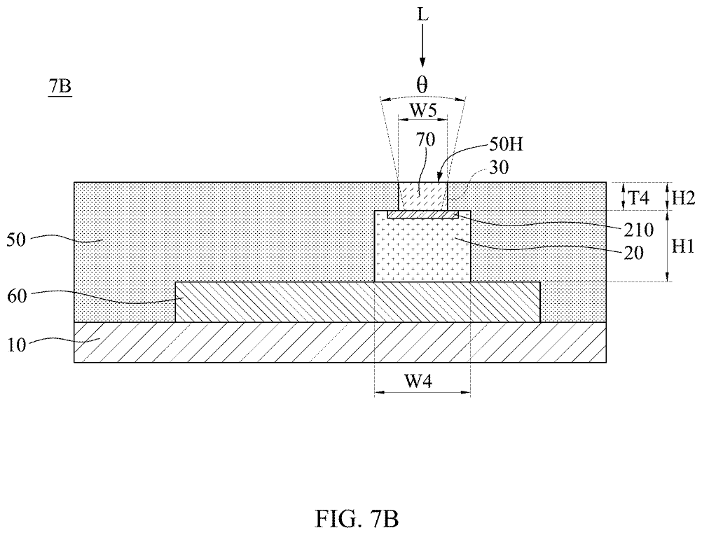

FIG. 7A illustrates a cross-sectional view of an optical device package 7A in accordance with some embodiments of the present disclosure. The optical device package 7A is similar to the optical device package 6 in FIGS. 6A-6B, and the differences therebetween are described as follows.

In some embodiments, the thickness T4 of the dummy die 70 is greater than the height H1 of the sensor 20. In some embodiments, a width W5 of the dummy die 70 is greater than a width W4 of the sensor 20. According to some embodiments of the present disclosure, the dummy die 70 can be used to further reduce the FOV by adjusting the thickness T4 of the dummy die 70 while the horizontal area of the optical device package 7A cannot be further reduced due to manufacturing processing limit.

FIG. 7B illustrates a cross-sectional view of an optical device package 7B in accordance with some embodiments of the present disclosure. The optical device package 7B is similar to the optical device package 6 in FIGS. 6A-6B, and the differences therebetween are described as follows.

In some embodiments, the dummy die 70 is stacked over the sensor 20 and surrounded by the light-blocking structure (e.g., the encapsulant 50). In some embodiments, the sensing region 210 is facing up toward the dummy die 70. In some embodiments, the height H2 of the light-transmitting region 30 equals to the thickness T4 of the dummy die 70.

According to some embodiments of the present disclosure, with the design of the dummy die 70 stacked over the sensor 20, the FOV of the optical device package 7B can be adjusted by varying the thickness T4 of the dummy die 70 and/or the width W5 of the dummy die 70, and thus the design flexibility can be increased. In addition, when the thickness T4 of the dummy die 70 and the thickness (the height H2) of the sensor 20 required to have certain predetermined values according to the applications, the sensing region 210 may be adjusted to face up toward the dummy die 70 to further adjust the FOV of the optical device package 7B.

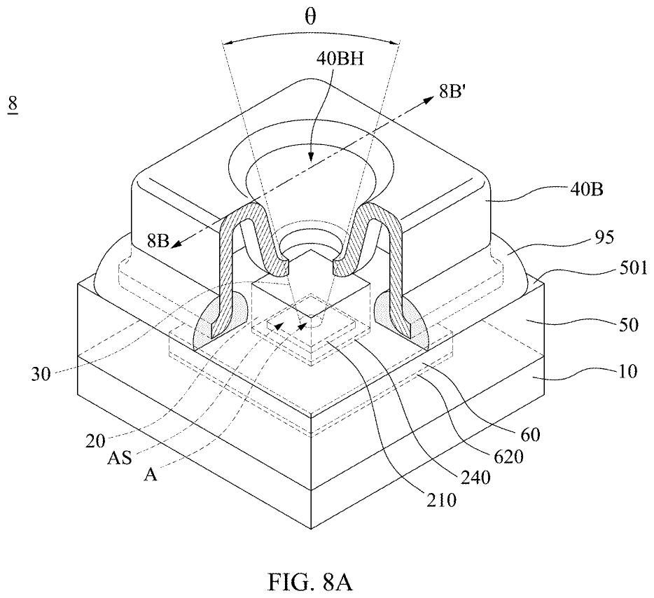

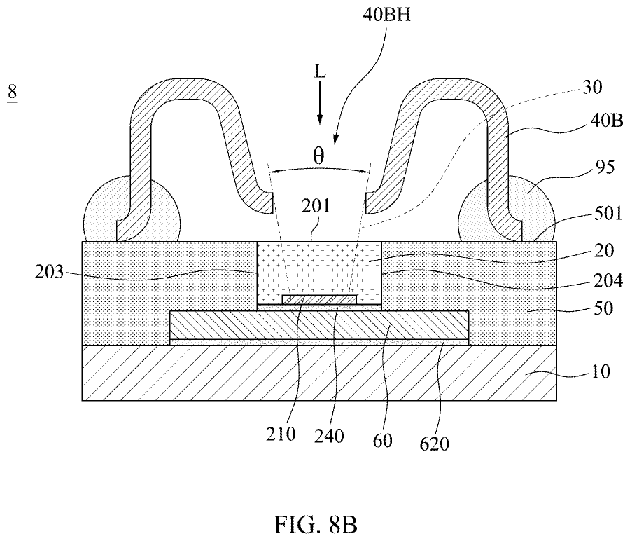

FIG. 8A illustrates a perspective view of an optical device package 8 in accordance with some embodiments of the present disclosure. FIG. 8B illustrates a cross-sectional view of an optical device package 8 in accordance with some embodiments of the present disclosure. In some embodiments, FIG. 8B illustrates a cross-sectional view along line 8B-8B′ in FIG. 8A. The optical device package 8 is similar to the optical device package 1 in FIGS. 1A-1B, and the differences therebetween are described as follows.

In some embodiments, the light-blocking structure of the optical device package 8 includes a light-blocking layer 40B and the encapsulant 50.

In some embodiments, the light-blocking layer 40B is over the sensor 20 and the encapsulant 50. In some embodiments, the light-blocking layer 40B is over the sensing region 210. In some embodiments, the light-blocking layer 40B is free from contacting the sensor 20. In some embodiments, the light-blocking layer 40B is or includes a metal lid. In some embodiments, the light-blocking layer 40B partially covers the surface 201 of the sensor 20. In some embodiments, the light-blocking layer 40B defines an opening 40BH exposing a portion of the surface 201 (or the top surface) of the sensor 20. In some embodiments, the light-transmitting region 30 includes a through hole (e.g., the opening 40BH) surrounded by the light-blocking layer 40B. In some embodiments, the through hole (e.g., the opening 40BH) is directly above and tapers toward the surface 201 (or the top surface) of the sensor 20. In some embodiments, the surface 201 of the sensor 20 is exposed to air. According to some embodiments of the present disclosure, with the design of the at least partially slanted profile of the opening 40BH (or the through hole) of the metal lid, the external light L may be directed and converged toward the sensing region 210 of the sensor 20, and thus the FOV of the optical device package 8 can be further reduced. In addition, the slanted profile of the opening 40BH of the light-blocking layer 40B (or the metal lid) is advantageous to reflect the large angle external light L (i.e., noise) out of the optical device package 8. Thus, it can further reduce noise and increase the amount or proportion of small angle external light L received by the sensing region 210. Therefore, an encapsulant to encapsulate the sensor 20 can be reduced, and thus the optical device package 8 can have a relatively small size in horizontal directions (e.g., in x-y plane) while the signal/noise (S/N) ratio of the received light (or received optical signal) can be reduced. In addition, the height of the light-transmitting region 30 may be adjusted by adjusting the thickness of the light-blocking layer 40B, so as to adjust the FOV of the optical device package 8.

In some embodiments, the optical device package 8 further includes an adhesive gel 95 fastening the light-blocking layer 40B (or the metal lid) to the top surface 501 of the encapsulant 50. In some embodiments, the adhesive gel 95 is formed of or includes a material opaque or light-blocking (or non-transmissive) to the external light L.

In some embodiments, the optical device package 8 further includes an adhesive layer 240 adhering the sensor 20 to the electronic component 60. In some embodiments, the optical device package 8 further includes an adhesive layer 620 adhering the electronic component 60 to the carrier 10. The adhesive layer 240 may be or include a conductive gel (e.g., a silver gel) to electrically connect the sensor 20 to the electronic component 60. In some embodiments, the adhesive layer 620 may be or include a conductive gel or an insulative gel.

In some embodiments, the optical device package 8 may include a light-limiting structure at least partially over the sensor 20 and configured to define a field-of-view (FOV) of the optical device package 8. In some embodiments, the light-limiting structure includes the light-blocking layer 40B (or the metal lid) with the opening 40BH tapering toward the surface 201 of the sensor 20. In some embodiments, the light-limiting structure further includes the adhesive gel 95.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of said numerical value, such as less than or equal to ±5%, less than or equal to ±4%, less than or equal to #3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to #10°, such as less than or equal to ±5°, less than or equal to ±4°, less than or equal to ±3º, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and the like. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. An optical device package, comprising:
a sensor comprising a sensing region; and
a light-transmitting region at least partially in the sensor, the light-transmitting region allowing an external light to transmit therethrough and reach the sensing region,
wherein a width of the light-transmitting region adjacent to a level of the sensing region is equal to or smaller than a width of the sensing region.

2. The optical device package as claimed in claim 1, wherein the width of the light-transmitting region adjacent to the level of the sensing region is in a direction substantially parallel to a diagonal line of the sensing region from a top view perspective.

3. The optical device package as claimed in claim 1, wherein an area of the light-transmitting region adjacent to the level of the sensing region is smaller than an area of the sensing region.

4. The optical device package as claimed in claim 1, wherein a width of a portion the light-transmitting region proximal to the sensing region is less than a width of a portion of the light-transmitting region distal from the sensing region.

5. The optical device package as claimed in claim 1, wherein the light-transmitting region is configured to allow mainly the external light having a wavelength range excluding a visible spectrum to transmit therethrough and reach the sensing region.

6. The optical device package as claimed in claim 1, further comprising a dummy die, wherein the light-transmitting region includes a portion of the dummy die.

7. The optical device package as claimed in claim 6, wherein a width of the dummy die is less than the width of the sensing region.

8. An optical device package, comprising:
a sensor comprising a sensing region;
a light-transmitting region adjacent to the sensing region and configured to allow an external light to transmit therethrough and reach the sensing region; and
a first light-limiting structure partially exposing the sensing region from a top view perspective, the sensing region and the first light-limiting structure are at opposite sides of the sensor.

9. The optical device package as claimed in claim 8, wherein the first light-limiting structure defines an aperture allowing the external light to transmit therethrough, and the first light-limiting structure comprises a first portion over the sensor and surrounding the aperture.

10. The optical device package as claimed in claim 9, further comprising a second light-limiting structure surrounding a lateral surface of the sensor and configured to block the external light from entering the sensor through the lateral surface.

11. The optical device package as claimed in claim 9, wherein the first portion comprises a non-metal layer and a metal coating defining a lateral side of the aperture.

12. The optical device package as claimed in claim 11, wherein the lateral side of the aperture is at least partially slanted, and the aperture has a width smaller than a width of a top surface of the sensor.

13. The optical device package as claimed in claim 8, wherein the first light-limiting structure has an outer edge substantially aligned with a lateral surface of the sensor.

14. The optical device package as claimed in claim 13, further comprising a second light-limiting structure encapsulating the sensor, wherein a top surface of the first light-limiting structure substantially aligns with a top surface of the second light-limiting structure.

15. An optical device package, comprising:
a carrier;
a sensor disposed over the carrier and comprising a sensing region;
a light-transmitting region adjacent to the sensing region and configured to allow an external light to transmit therethrough and reach the sensing region; and
a light-limiting structure defining a light-transmitting area at a side of the light-transmitting region away from the sensing region, wherein a distance between the sensing region and the light-transmitting area is configured to reduce a distance between a top surface of the light-limiting structure and the carrier.

16. The optical device package as claimed in claim 15, wherein the sensing region and the light-limiting structure are at opposite sides of the sensor.

17. The optical device package as claimed in claim 16, wherein a distance between the sensing region and the carrier is less than a distance between the sensing region and the light-limiting structure.

18. The optical device package as claimed in claim 15, further comprising a processing component electrically connected to the sensor, wherein the carrier is light-blocking, and the light-limiting structure further comprises an encapsulant encapsulating the sensor and the processing component.

19. The optical device package as claimed in claim 15, further comprising a connection layer between the light-limiting structure and the sensor, wherein the connection layer comprises a light-blocking material.

20. The optical device package as claimed in claim 15, wherein at least a portion of the sensing region is embedded in the light-transmitting region.
